(19) United States
(12) Patent Application Publication
(10) Pub. No.: US 2009/0108905 A1
(43) Pub. Date: Apr. 30, 2009

(54) Dynamic NP-swappable body bias circuit

(75) Inventors: Jinn-Shyan Wang, Min-Hsiung Chia-Yi (TW); Jian-Shiun Chen, Min-Hsiung Chia-Yi (TW); Ching-wei Yeh, Min-Hsiung Chia-Yi (TW)

Correspondence Address: TROXELL LAW OFFICE PLLC, SUITE 1404, 5205 LEESBRUG PIKE, FALLS CHURCH, VA, 22041, US

(73) Assignee: National Chung Cheng University, Chia-Yi (TW)

(21) Appl. No.: 11/976,445

(22) Filed: Oct. 24, 2007

(51) Int. Cl. H03K 17/04

(52) U.S. Cl. 327/374; 327/534

(57) ABSTRACT

A dynamic NP-swappable body bias circuit includes a core circuit, a power switch and a body bias controller. The core circuit includes a body bias terminal. The power switch includes a body bias terminal, and connects the core circuit to an external voltage supply. The body bias controller is connected to the body bias terminals of the core circuit and the power switch so that the power switch and the core circuit are under the control of the body bias controller.

### BACKGROUND OF INVENTION

1. Field of Invention

The present invention relates to a dynamic NP-swappable body bias circuit and, more particularly, to a dynamic NP-swappable body bias circuit for increasing the operation speed and reducing the power dissipation at a low or an ultra low workable supply voltage.

2. Related Prior Art

Portable devices are becoming popular. Standby power is a critical factor for duration. A CMOS process can expedite the increased operation speed of a circuit, it however entails a worst leakage current. To make a portable device better and faster, one has to reduce the standby power.

In previous SLVCMOS researches, low-voltage operations and power gating are widely used to reduce the power dissipation. In the power gating, turn the idle power islands off to reduce the standby power. Moreover, according to a well-knew notion, P=αCV_{DD}²f, the best way to reduce the power dissipation is to reduce the operation voltage. However, if the operation voltage is reduced, the operation frequency will also be reduced. The speed of the circuit might be too low. Furthermore, the performance loss by the power gating must be compensated.

The present invention is therefore intended to obviate or at least alleviate the problems encountered in prior art.

### SUMMARY OF INVENTION

The primary objective of the present invention is to provide a bias circuit for increasing the operation speed and reducing the power dissipation at a low or an ultra low workable supply voltage.

To achieve the primary objective of the present invention, a dynamic NP-swappable body bias circuit includes a core circuit, a power switch and a body bias controller. The core circuit connects to the external voltage supply through the power switch. The body bias controller is connected to the body terminals of the core circuit and the power switch so that the body bias of the power switch and the core circuit are under the control of the body bias controller.

Other objectives, advantages and features of the present invention will become apparent from the following description referring to the attached drawings.

### BRIEF DESCRIPTION OF DRAWINGS

The present invention will be described via detailed illustration of the preferred embodiment referring to the drawings.

FIG. 1 is a diagram of a dynamic NP-swappable body bias circuit according to the preferred embodiment of the present invention.

FIG. 2 is a diagram of the layout of a standard cell of a core circuit of the dynamic NP-swappable body bias circuit shown in FIG. 1.

FIG. 3 is a cross-sectional view of the dynamic NP-swappable body bias circuit shown in FIG. 1.

FIG. 4 is a microphotograph of a chip embodying the dynamic NP-swappable body bias circuit shown in FIG. 1.

FIG. 5 is a chart of the measured operation speed versus the supply voltage of the dynamic NP-swappable body bias circuit shown in FIG. 1.

FIG. 6 is a chart of the measured power dissipation versus the supply voltage of the dynamic NP-swappable body bias circuit shown in FIG. 1.

### DETAILED DESCRIPTION OF PREFERRED EMBODIMENT

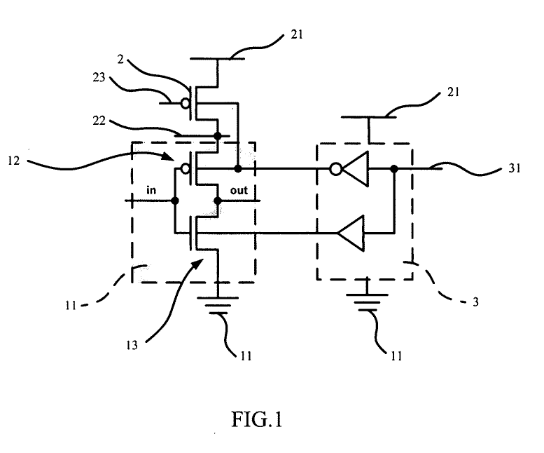

Referring to FIG. 1, a dynamic NP-swappable body bias circuit includes a core circuit 1, a power switch 2 and a body bias controller 3 according to the preferred embodiment of the present invention. The dynamic NP-swappable body bias circuit not only increases the operation speed but also reduces the power dissipation at a low or an ultra low workable supply voltage.

The core circuit 1 is connected to an external voltage supply through a node 21 of the power switch 2. An internal node 22 of the power switch 2 is used as a virtual supply terminal of the core circuit 1. On the other hand, the core circuit 1 is directly connected to a ground terminal 11, not through the power switch 2. The core circuit 1 includes a PMOS 12 and a NMOS 13. The PMOS 12 include a body terminal connected to the body bias controller 3. The NMOS 13 includes a body terminal connected to the body bias controller 3. The power switch 2 a body terminal connected to the body bias controller 3. When operated at a low or ultra low voltage, the value of a forward body bias does not exceed that of the external voltage supply. Therefore, the body bias controller 3 can be a simple inverter connected to an internal supply terminal and the ground terminal 11, without the need for an extra circuit to generate a reference voltage. In use, the body bias controller 3 provides the core circuit 1 with a forward body bias to increase the operation speed. The power switch 2 is turned on for energizing the core circuit 1. When the circuit is idle, a zero body bias is generated for reducing a leakage current caused by the body bias. The power switch 2 is closed to suppress the current of the leakage path of the core circuit 1.

In the preferred embodiment, if the control terminal 23 of the power switch 2 is used with the control terminal 31 of the body bias controller 3, there will be a relation of inverted phases between them. The relation between them can be varied to satisfy different needs.

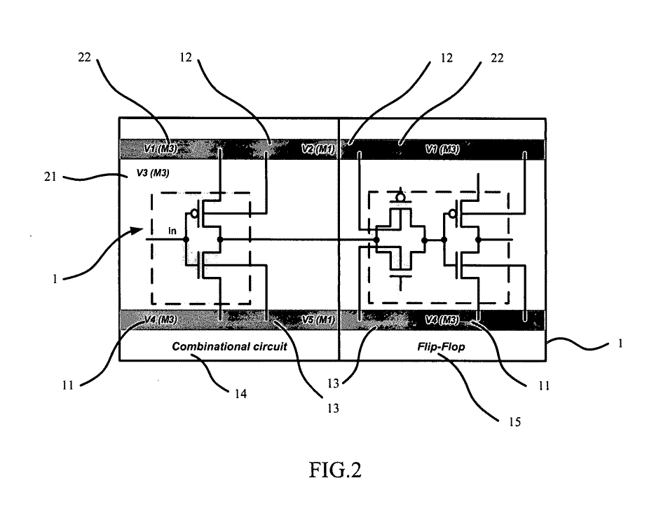

Referring to FIG. 2, the core circuit 1 includes a combinational logic 14 and a sequential logic 15. To save the area of the core circuit 1, internal logic gates are packed. There are five power rails: the virtual supply terminal 22, the actual ground terminal 11, the PMOS 12, the NMOS 13 and the actual supply terminal 21. A multi-rail standard cell is used for the interconnection of the power rails. V1 is the virtual supply terminal 22, and Metal 3 is used in an upper portion of the logic gate. V2 is the body terminal of the PMOS 12 of the core circuit 1 and the body terminal of the power switch 2, and Metal 1 is used in an upper portion of the logic gate and overlapped with V1. V3 is the actual supply terminal 21, and Metal 3 is used in an upper portion of the logic gate and parallel to V1. V4 is the actual ground terminal 11, and Metal 3 is used in a lower portion of the logic gate. V5 is the body terminal of the NMOS 13 of the core circuit 1, and Metal 1 is used in a lower portion of the logic gate and overlapped with V4.

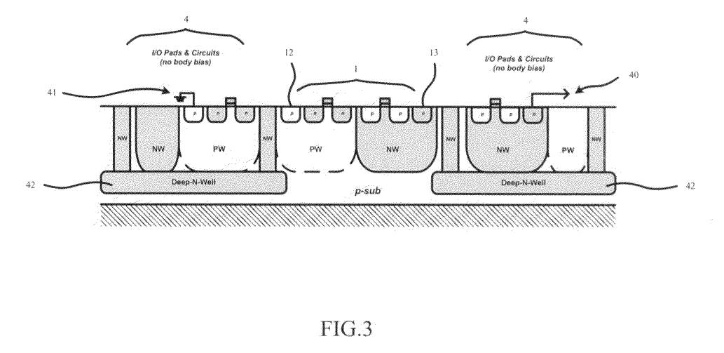

Referring to FIG. 3, when the dynamic PN-swappable body bias circuit is embodied in a CMOS process, the positive well (“PW”) and the positive substrate (“P-Substrate”) are identical in bias. Hence, when the NMOS 13 of the core circuit 1 is provided with a forward body bias, all of the NMOS 13 of the entire integrated circuit are affected. A deep negative well (“DNW”) 42 is used to isolate a circuit 4 not in need of a forward body bias. Examples include an input/output pad (“I/O pad”), a positive well 41 and a negative well 40.

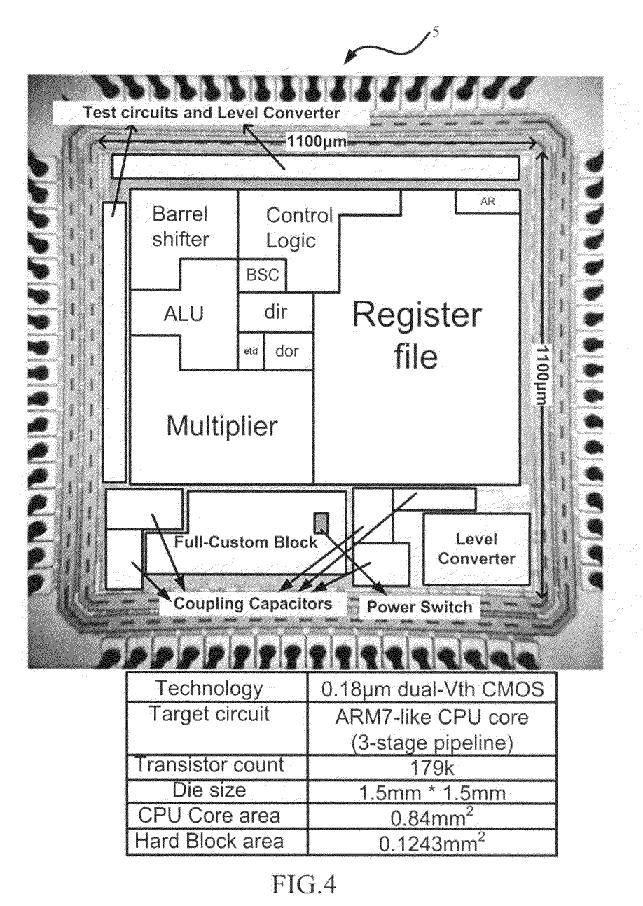

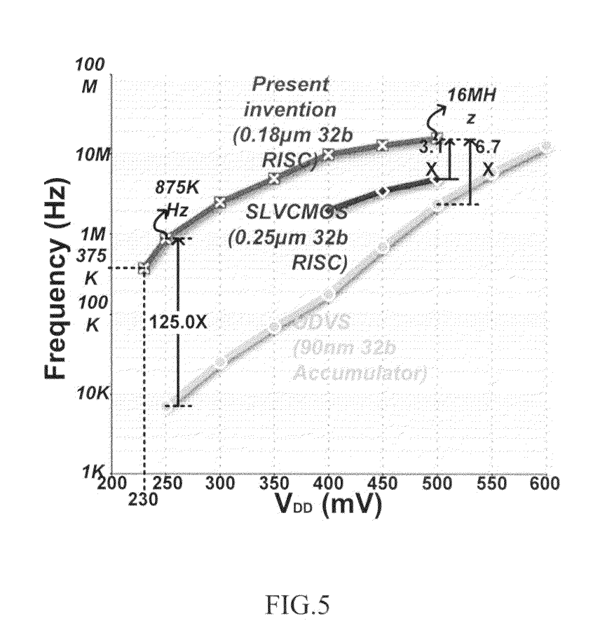

Referring to FIGS. 4 through 6, the dynamic PN-swappable body bias circuit is embodied in a 32-bit RISC core of a chip 5 made in a 0.18 mm dual-Vth CMIS process. The size of the chip 5 is 1.5 mm×1.5 mm. The size of the RISC core is 0.84 mm². The area of the full-custom hardware is 0.1243 mm². The internal area of the chip 5 according to the present invention is about 67% smaller than that of the SLVCMOS. Referring to FIG. 5, compared with the SLVCMOS and UDVS, the present invention can be operated at a lower operation voltage of 230 mV. At 500 mV and 250 mV, the performance is considerably improved. At 250 mV, the present invention is 125 times faster than the UDVS. Although made with worse wiring in a worse process, the present invention still makes improvement over the prior art.

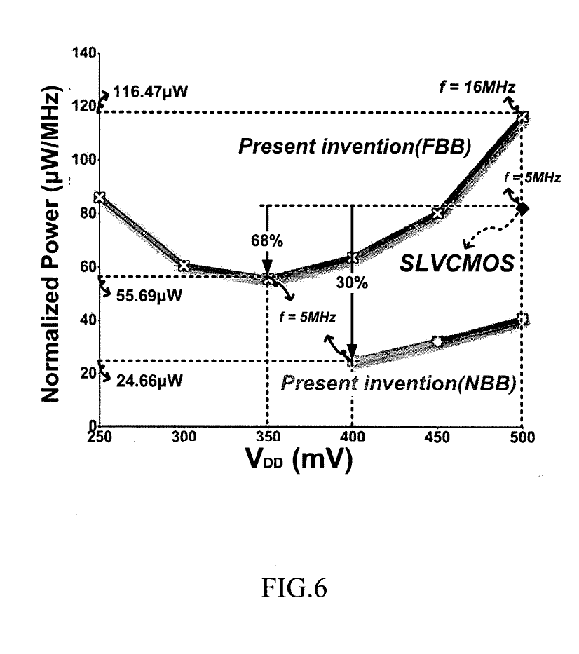

Referring to FIG. 6, at a same operation frequency of 5 MHz, the present invention reduces the power dissipation by 68% with the forward body bias and by 30% with the zero body bias. At 500 mV, with the forward body bias, the operation speed of the present invention is about 3 times faster than that of the SLVCMOS although dissipating more power. If the power dissipation is the primary concern, the zero body bias can be used, and the power dissipation of the present invention can be much less than that of the SLVCMOS.

As discussed above, the dynamic NP-swappable body bias circuit increases the operation speed and reduces the power dissipation at a very low workable supply voltage.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A dynamic NP-swappable body bias circuit comprising:
a core circuit comprising a body bias terminal;
a power switch comprising a body bias terminal wherein the power switch connects the core circuit to an external voltage supply; and
a body bias controller connected to the body bias terminals of the core circuit and the power switch are connected to a body bias controller so that the biases are under the control of the body bias controller.

2. The dynamic NP-swappable body bias circuit according to claim 1, wherein the power switch receives external control signals to turn on or off the core circuit.

3. The dynamic NP-swappable body bias circuit according to claim 1, wherein the core circuit is to a ground terminal through the power switch.

4. The dynamic NP-swappable body bias circuit according to claim 1, wherein the body bias controller receives external control signals to swap the body bias of the core circuit and the power switch.

5. The dynamic NP-swappable body bias circuit according to claim 1, wherein the core circuit comprises a combinational logic and a sequential logic.

6. The dynamic NP-swappable body bias circuit according to claim 5, wherein the sequential logic comprises a supply terminal directly connected to the external voltage supply so that the external voltage supply provides a proper voltage to the sequential logic to retain an internal logic value.

7. The dynamic NP-swappable body bias circuit according to claim 5, wherein the sequential logic comprises a supply terminal connected to the external voltage supply through the power switch in cooperation with a storage element.
